(19) United States
(12) Patent Application Publication
(10) Pub. No.: US 2004/0100780 A1
(43) Pub. Date: May 27, 2004

(54) Motherboard power-leveler

(76) Inventors: Brent Stone, Chandler, AZ (US); Dustin Wood, Chandler, AZ (US)

Correspondence Address: Vani Moodley, BLAKELY, SOKOLOFF, TAYLOR & ZAFMAN LLP, Seventh Floor, 12400 Wilshire Boulevard, Los Angeles, CA, 90025-1026, US

(21) Appl. No.: 10/306,388

(22) Filed: Nov. 27, 2002

(51) Int. Cl. H05K 7/06

(52) U.S. Cl. 361/760; 361/783; 257/691

(57) ABSTRACT

In one embodiment there is provided a motherboard assembly. The motherboard assembly comprises a motherboard substrate; a conductive circuit on a first side of the motherboard substrate comprising an interface to connect the conductive circuit to an electrical component; and a power leveling element aligned with the interface and mounted to a second side of the motherboard substrate opposite the first side, the power leveling element being to level power delivery from the interface.

### FIELD OF THE INVENTION

This invention relates to motherboards. In particular, it relates to power routing in motherboards.

### BACKGROUND

As used herein, the term “motherboard” refers generally to any carrier for circuits or components. Generally, a motherboard comprises a motherboard substrate and a conductive circuit printed thereon to route power from a power supply to a electrical component, e.g., a microprocessor, mounted on the motherboard. The electrical component may be mounted on a surface of the motherboard, or it may be mounted within a socket in the motherboard. In the case of a surface mounting, electrical interconnection elements such as pins or gold-plated lands of the electrical component mate with complementary socket formations to electrically interconnect the electrical component to the motherboard. In the case of a surface mounting, a ball grid array (BGA) comprising a plurality of solder balls is soldered into electrical contact with the motherboard.

The electrical interconnection elements may be disposed to define a power routing configuration, wherein some of the electrical interconnection elements occur at opposed ends of the electrical component. Thus, the electrical interconnection elements at one end of the electrical component may be closer to a power supply than the electrical interconnection elements at the opposite end of the electrical component. For example, in one power routing configuration, the electrical interconnection elements may be in the form of pins located at a north and south end of the electrical component. The pins at the north end will hereinafter be referred as to the “north pins”, and the pins at the south end will hereinafter be referred to as the “south pins”. Even in a power routing configuration in which all the electrical interconnection elements are located at one end of the electrical component, the electrical interconnection elements may have a spacial configuration such that some of the electrical interconnection elements may be located closer to the power supply than others.

These power routing configurations result in a non-uniform current flow through the north and south pins, respectively. This is illustrated in FIG. 1 of the drawings, which shows a simplified circuit for current flow through a motherboard.

Referring to FIG. 1, V represents the voltage supplied by the power supply, R_{MB} represents the motherboard resistance, R_{South} and R_{North} represent the resistance of the north and south pins, respectively.

Assuming R_{South}=R_{North}=R, then the current flowing through the south pins and north pins, is expressed as Equation 1 and Equation 2 below, respectively.

$$\begin{matrix}{I}_{South} = {I}_{l n} * ( \frac{R}{( R + {R}_{MB} ) + R} ) & [ Equation 1 ] \\ {I}_{North} = {I}_{l n} * ( \frac{R + {R}_{MB}}{( R + {R}_{MB} ) + R} ) & [ Equation 2 ]\end{matrix}$$

The ratio of these currents, expressed in Equation 3, indicates the level of non-uniformity in current flowing through the north and south pins.

$$Ratio = \frac{{I}_{South}}{{I}_{North}} = \frac{R}{R + {R}_{MB}} \qquad [ Equation 3 ]$$

When the motherboard resistance is extremely low, i.e. R_{MB}→0; Ratio=1 then the current flowing through each side is uniform. When the motherboard resistance is extremely high, i.e., when R_{MB}→∞; Ratio=0 then all the current flows through the south side and therefore is extremely non-uniform.

The conductive circuit provides a conductive path between a respective pair of north and south pins. The resistance of each of these paths, determines the magnitude of the current flow therethrough, as discussed above. Thus, non-uniformity in these resistances cause corresponding non-uniformity of current flow through each of the parts, as discussed above. The consequence of this non-uniform current flow is that it leads to non-uniform power dissipation, and heating, which raises potential reliability problems.

This problem of the non-uniform current flow occurs whenever there is a power routing configuration in which some of the electrical interconnection elements are closer to a power supply than other electrical interconnection elements. Thus, this problem may occur in a power routing configuration that has north and south pins, as discussed above, east and west pins, solder balls disposed in a ball grid array, or in the case of conductive lands in a land grid array (LGA).

One attempt to solve this problem of non-uniform current flow is to increase the number of layers within the motherboard, each layer carrying a conductive circuit. Another attempt at solving the problem of non-uniform current flow is to increase the density of current paths within a circuit on the motherboard. Each of these solutions are expensive to implement.

### BRIEF DESCRIPTION OF THE DRAWINGS

FIG. 1 shows a prior art technique of addressing the non-uniform distribution of current to an electrical element;

FIG. 2 shows an exploded perspective view of a motherboard assembly in accordance with one embodiment of the invention; and

FIG. 3 shows a side view of the motherboard assembly of FIG. 2.

### DETAILED DESCRIPTION

In the following description, for purposes of explanation, numerous specific details are set forth in order to provide a thorough understanding of the invention. It will be apparent, however, to one skilled in the art that the invention can be practiced without these specific details. In other instances, structures and devices are shown in block diagram form in order to avoid obscuring the invention.

Reference in this specification to “one embodiment” or “an embodiment” means that a particular feature, structure, or characteristic described in connection with the embodiment is included in at least one embodiment of the invention. The appearances of the phrase “in one embodiment” in various places in the specification are not necessarily all referring to the same embodiment, nor are separate or alternative embodiments mutually exclusive of other embodiments. Moreover, various features are described which may be exhibited by some embodiments and not by others. Similarly, various requirements are described which may be requirements for some embodiments but not other embodiments.

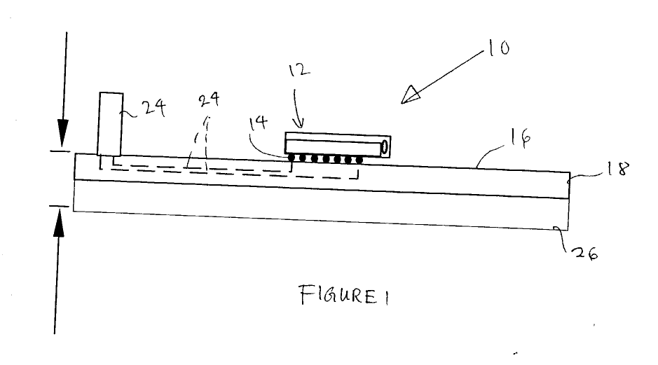

FIG. 1 of the drawings shows a side view of a high level block diagram of a motherboard assembly 10 comprising an electrical component in the form of a microprocessor 12, which is surface mounted via solder balls 14 to an upper surface 16 of a motherboard 18. Each solder ball 14 is in electrical contact with a power routing circuit 22 of the motherboard 18 which routes power from a power supply 24 to each of the solder balls 14. The solder balls 14 are disposed in an array comprising rows of solder balls such that a row of solder balls at one end of the microprocessor 12 is closer to the power supply 24 than a row of solder balls located at the opposite end of the microprocessor 12. For example, the row of solder balls that is closer to the power supply 24 may be located at a north end of the microprocessor 12, whereas the row of solder balls furthest from the power supply 24 may be located at a south end of the microprocessor 12. In other configurations, the row of solder balls that is closest to the power supply 24 may be located at an east end of the microprocessor 12, whereas the row of solder balls that is located furthest from the power supply 24 may be located at a west end of the microprocessor 12. The exact designation of the solder balls as being located at an east, a west, a north or a south end of the microprocessor 12 is not important. What is important, however, is that the solder balls, which are representative of electrical interconnection elements and which may be electrical pins, electrical lands, etc., in other embodiments, are disposed in a spatial configuration, in which the solder balls at one end of the microprocessor 12 are closer to the power supply 24 than the solder balls at the opposite end of the microprocessor 12.

As a result of such a spatial configuration of the electrical interconnection elements, and as described above, there would be a non-uniform current distribution to the solder balls 14 such that the solder balls that are closest to the power supply 24 will have a higher current flow therethrough than the solder balls that are furthest away from the power supply 24.

As explained above, this non-uniform current flow leads to non-uniform power dissipation, and heating, which gives rise to reliability problems.

According to techniques of the prior art, one technique which attempts to solve this problem includes adding layers, represented by reference numeral 26 in FIG. 1 of the drawings, to the motherboard 18, wherein each layer comprises conductive circuitry which adds additional conductive pathways between the power supply 24 and the solder balls 14. This solution is difficult to implement, and adds to the complexity of the motherboard 18.

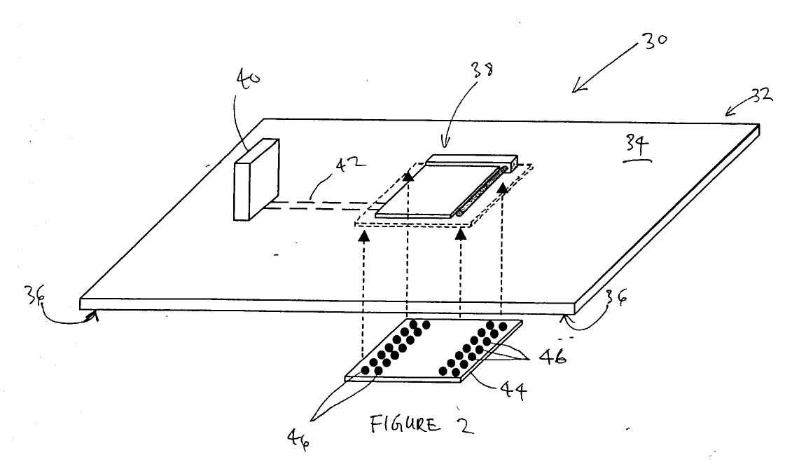

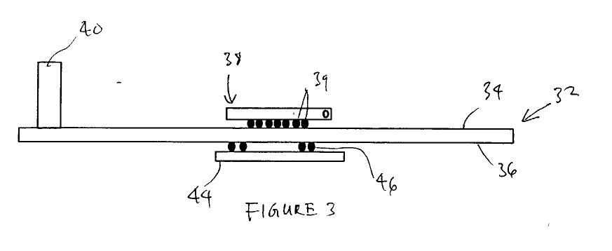

Referring now to FIGS. 2 and 3 of the drawings, reference numeral 30 generally indicates a motherboard assembly in accordance with one embodiment of the present invention. The motherboard assembly 30 includes a motherboard 32 comprising an operatively upper surface 34, and an operatively lower surface 36. The motherboard assembly 30 further comprises an electrical component 38 which, could, for example, be a microprocessor. Electrical component 38 may be surface mounted to the upper surface 34 of the motherboard 32 through interconnection elements in the form of solder balls 39 disposed in a ball grid array (BGA). Alternatively, the electrical component 38 may be surface mounted within a socket which opens on the upper surface 34 of the motherboard 32. The socket may be a land grid array (LGA) type socket and the electrical interconnection elements may be in the form of gold plated electrical lands. Alternatively, the electrical interconnection elements may be in the form of electrical pins which mate with complementary formations in a corresponding socket of the motherboard 32.

A power supply 40 routes power through a conductive circuit 42 to electrical interconnection elements.

As noted above, whenever the electrical interconnection elements are disposed in a spatial configuration in which some of the electrical interconnection elements are closer to the power supply 40 than others, the problem of non-uniform current distribution occurs. In order to address this problem, the motherboard assembly 30 further comprises a conductive element 44 which is mounted to the underside 36 of the motherboard 32, immediately under the electrical component 38. The purpose of the conductive element 44 is to provide an alternative, non-motherboard electrical path through which current may be routed to the electrical interconnection elements that are furthest from the power supply 40. In one embodiment, the conductive element 44 may be a planar conductive element and may include a conductive metal substrate, such as a copper substrate. In other embodiments, the conductive element may be in the form of a circuit board comprising conductive lines printed thereon. Electrical interconnection between the conductive element 44 and the underside 36 of the motherboard 32 may be achieved in various ways. For example, the conductive element 44, which may be conveniently referred to as a power-leveler, may be connected to the underside 36 of the motherboard 32 through a surface mount process. The surface mount process may be accomplished by incorporation of solder balls on a surface of the power-leveler 44. In the embodiment of the power-leveler shown in FIG. 2 of the drawings, reference numeral 46 indicates one embodiment of these solder balls. The solder balls may be attached to the motherboard 32 through the use of a standard paste print and reflow surface mount process.

In another embodiment, the power-leveler (conductive element) 44 may take the form of a lead frame package comprising metal leads that are integrated within the package. This package may be surface mounted to the motherboard 32 through a standard paste print and reflow mount process.

In yet a further embodiment, a Land Grid Array (LGA) socket type connection may be used to achieve electrical interconnection between the electrical (conductive element) 44 and the motherboard 32. In this embodiment, the electrical interconnection lands may be located on the motherboard 32, and the power-leveler (conductive element) 44 may comprise electrical contacts to provide an electrical connection when a sustained compressive load is provided between the motherboard and the power-leveler (conductive element) 44.

In yet another embodiment, the power-leveler (conductive element) 44 may be press-fitted into a complementary socket on the underside 36 of the motherboard 32. For example, the motherboard 32 may be provided with holes, typically through-hole vias, and the power-leveler (conductive element) 44 may comprise metal leads so that the power-leveler (conductive element) 44 may be press fitted into the holes in the motherboard 32.

The exact method by which electrical interconnection between the electrical conductive element 54 and the underside 36 of the motherboard 32 may thus vary in different embodiments. However, in each case, when the electrical interconnection between the electrical conductive element 44 and the underside 36 of the motherboard 32 is achieved, there is provided an alternative non-motherboard pathway for the power to be routed to the electrical interconnection elements that are furthest from the power supply 40.

Although the present invention has been described with reference to specific exemplary embodiments, it will be evident that the various modification and changes can be made to these embodiments without departing from the broader spirit of the invention as set forth in the claims. Accordingly, the specification and drawings are to be regarded in an illustrative sense rather than in a restrictive sense.

What is claimed is:

1. A method, comprising:
changing a power routing configuration of a motherboard by providing an additional non-motherboard current path.

2. The method of claim 1, wherein providing the additional non-motherboard current path comprises mounting a conductive element to a region of the motherboard where the current is to be altered.

3. The method of claim 2, wherein the conductive element comprises a circuit board comprising conductive lines printed thereon.

4. The method of claim 2, wherein the conductive element comprises a conductive metal plate.

5. The method of claim 2, wherein mounting the conductive element comprises electrically interconnecting the conductive element to an underside of the motherboard using conductive bumps.

6. The method of claim 2, wherein the region of the motherboard corresponds to that region of the motherboard where a high powered component is located.

7. The method of claim 6, wherein the high powered component is a microprocessor.

8. A motherboard assembly, comprising:
a motherboard substrate;
a conductive circuit on a first side of the motherboard substrate comprising an interface to connect the conductive circuit to an electrical component; and
a power leveling element aligned with the interface and mounted to a second side of the motherboard substrate opposite the first side, the power leveling element being to level power delivery across the interface.

9. The motherboard assembly of claim 8, wherein the interface comprises a socket.

10. The motherboard assembly of claim 9, wherein the power leveling component comprises a conductive element having a surface area matched to the surface area of the socket.

11. The motherboard assembly of claim 10, wherein the conductive element comprises a circuit board comprising conductive lines printed thereon.

12. The motherboard assembly of claim 10, wherein the conductive element comprises a conductive metal plate.

13. The motherboard assembly of claim 8, wherein the power-leveler is mounted through conductive bumps soldered between the conductive element and the second side of the motherboard substrate.

14. A system, comprising:
a motherboard comprising a motherboard substrate, a conductive circuit on a first side of the motherboard substrate and having an interface to connect to an electrical component;
a power leveling element mounted to a second side of the motherboard substrate opposite the first side, and aligned with the interface to provide a non-motherboard path for current to pins at opposite ends of the interface;
a power supply to supply power to the conductive circuit; and
an electrical device mounted to the interface.

15. The system of claim 14, wherein the interface comprises a socket.

16. The system of claim 14, wherein the power leveling element comprises a circuit board with conductive lines printed thereon.

17. The system of claim 14, wherein the power leveling element comprises a conductive metal plate.

18. The system of claim 14, wherein the power leveling element is mounted to the second side of the motherboard by conductive bumps disposed between the power leveling element and the second side.

19. The system of claim 14, wherein the electrical device comprises a microprocessor.
